(19) United States
(12) Patent Application Publication
(10) Pub. No.: US 2013/0064494 A1
(43) Pub. Date: Mar. 14, 2013

(54) ENCAPSULATION OF A TEMPERATURE COMPENSATIONING STRUCTURE WITHIN AN OPTICAL CIRCUIT PACKAGE ENCLOSURE

(71) Applicants: Cristian Bolle, City of Bridgewater, NJ (US); Mark Earnshaw, City of Morristown, NJ (US)

(72) Inventors: Cristian Bolle, City of Bridgewater, NJ (US); Mark Earnshaw, City of Morristown, NJ (US)

(21) Appl. No.: 13/228,636

(22) Filed: Sep. 9, 2011

(51) Int. Cl. G02B 6/122; H01L 31/18; G02B 6/13

(52) U.S. Cl. 385/14; 438/65; 257/E31.063

(57) ABSTRACT

An optical circuit package comprising a substrate having a planar surface and an interferometric planar lightwave circuit located on the planar surface of the substrate. A refractive-index-compensation material is incorporated into a portion of the planar lightwave circuit such that an optical path through the planar lightwave circuit passes through the refractive-index-compensation material. The package also comprises a moisture or organic vapor sensitive electro-optic device located on the substrate. An inner hermetic can is located on the substrate, wherein the inner hermetic can encapsulates the portion of the planar lightwave circuit incorporating the refractive-index-compensation material. An outer hermetic can is located on or around the substrate, wherein the outer hermetic can encloses the planar lightwave circuit, the moisture or organic vapor sensitive electro-optic device and the inner hermetic can.

### TECHNICAL FIELD

The present disclosure is directed, in general, to an optical communication system and more specifically, an optical receiver, and, methods of manufacturing the same.

### BACKGROUND

This section introduces aspects that may be helpful to facilitating a better understanding of the inventions. Accordingly, the statements of this section are to be read in this light. The statements of this section are not to be understood as admissions about what is in the prior art or what is not in the prior art.

Some optical circuit packages include planar lightwave circuits and moisture or organic vapor sensitive electro-optic devices. Because they are moisture sensitive, it is sometimes desirable to enclose the moisture or organic vapor sensitive electro-optic device in a hermetically sealed package. Because the refractive index of the planar lightwave circuits is sensitive to temperature, it is sometimes desirable to replace a portion of its optical path with a refractive-index-compensation material.

### SUMMARY OF THE INVENTION

One embodiment of the disclosure is an optical circuit package. The package comprises a substrate having a planar surface and an interferometric planar lightwave circuit located on the planar surface of the substrate. A refractive-index-compensation material is incorporated into a portion of the planar lightwave circuit such that an optical path through the planar lightwave circuit passes through the refractive-index-compensation material. The package also comprises a moisture or organic vapor sensitive electro-optic device located on the substrate. An inner hermetic can is located on the substrate, wherein the inner hermetic can encapsulates the portion of the planar lightwave circuit incorporating the refractive-index-compensation material. An outer hermetic can is located on or around the substrate, wherein the outer hermetic can encloses the planar lightwave circuit, the moisture or organic vapor sensitive electro-optic device and the inner hermetic can.

Another embodiment is a method of manufacturing an optical circuit package. The method comprises forming an interferometric planar lightwave circuit located on a planar surface of a substrate. A refractive-index-compensation material is incorporated into a portion of the planar lightwave circuit located such that an optical path through the planar lightwave circuit passes through the refractive-index-compensation material. A moisture or organic vapor sensitive electro-optic device is placed on the substrate. An inner hermetic can is formed on the substrate so as to encapsulate the portion of the planar lightwave circuit incorporating the refractive-index-compensation material. An outer hermetic can is formed on or around the substrate so as to enclose the planar lightwave circuit, the moisture or organic vapor sensitive electro-optic device and the inner hermetic can.

### BRIEF DESCRIPTION OF THE DRAWINGS

The embodiments of the disclosure are best understood from the following detailed description, when read with the accompanying FIGUREs. Some features in the figures may be described as, for example, “top,” “bottom,” “vertical” or “lateral” for convenience in referring to those features. Such descriptions do not limit the orientation of such features with respect to the natural horizon or gravity. Various features may not be drawn to scale and may be arbitrarily increased or reduced in size for clarity of discussion. Reference is now made to the following descriptions taken in conjunction with the accompanying drawings, in which:

FIG. 1 shows a plan view of an example optical circuit package of the disclosure;

FIG. 2 shows a detailed plan view of a portion of the example optical circuit package presented in FIG. 1, corresponding to view 2 in FIG. 1;

FIG. 3 shows a cross-sectional view of a portion of the example optical circuit package, depicted along in view lines 3-3 in FIG. 2; and

FIG. 4 presents a flow diagram of example method of manufacturing an optical circuit package according to the disclosure, such as any of the example packages discussed in the context of FIGS. 1-3.

### DETAILED DESCRIPTION

The description and drawings merely illustrate the principles of the invention. It will thus be appreciated that those skilled in the art will be able to devise various arrangements that, although not explicitly described or shown herein, embody the principles of the invention and are included within its scope. Furthermore, all examples recited herein are principally intended expressly to be only for pedagogical purposes to aid the reader in understanding the principles of the invention and the concepts contributed by the inventor(s) to furthering the art, and are to be construed as being without limitation to such specifically recited examples and conditions. Moreover, all statements herein reciting principles, aspects, and embodiments of the invention, as well as specific examples thereof, are intended to encompass equivalents thereof. Additionally, the term, “or,” as used herein, refers to a non-exclusive or, unless otherwise indicated. Also, the various embodiments described herein are not necessarily mutually exclusive, as some embodiments can be combined with one or more other embodiments to form new embodiments.

The present disclosure benefits from the discoveries made when manufacturing optical devices where a refractive-index-compensation material was incorporated into an arrayed waveguide grating and then the arrayed waveguide grating and avalanche photodiode detectors on the substrate were hermetically sealed inside an enclosure, referred to herein as a hermetic can, located on the substrate. The hermetic can is designed to prevent the penetration of water vapor present in the surrounding atmosphere, and thereby protect the avalanche photodiode detectors from damage from moisture.

Surprisingly, it was found that the avalanche photodiode detectors in optical devices still rapidly (e.g., within weeks or months) broke down from exposure to moisture. It was discovered that the avalanche photodiode detectors broke down due to exposure to moisture released from the refractive-index-compensation material incorporated into the arrayed waveguide grating. That is, the refractive-index-compensation material contained amounts of water or volatile organic compounds that were detrimental to the avalanche photodiode detectors.

In certain embodiments of the present disclosure, the problem of preventing exposure of the avalanche photodiode detector to moisture released by the refractive-index-compensation material was addressed by forming a hermetic can around the portion of the arrayed waveguide grating having the refractive-index-compensation material. Thus, an inner hermetic can encapsulates at least the portion of the arrayed waveguide grating having the refractive-index-compensation material, and, an outer hermetic can encloses both the arrayed waveguide grating and the avalanche photodiode detectors.

It was realized, as part of the present disclosure, that the above described solution could apply to any interferometric planar lightwave circuit and any moisture or organic vapor sensitive electro-optic device, and not just arrayed waveguide grating and avalanche photodiode detectors, respectively.

One embodiment of the present disclosure is an optical circuit package. Some embodiments of an optical circuit package can be configured as an optical transmitter component, or, an optical receiver component, or both, in a communication system, such as an optical transceiver system.

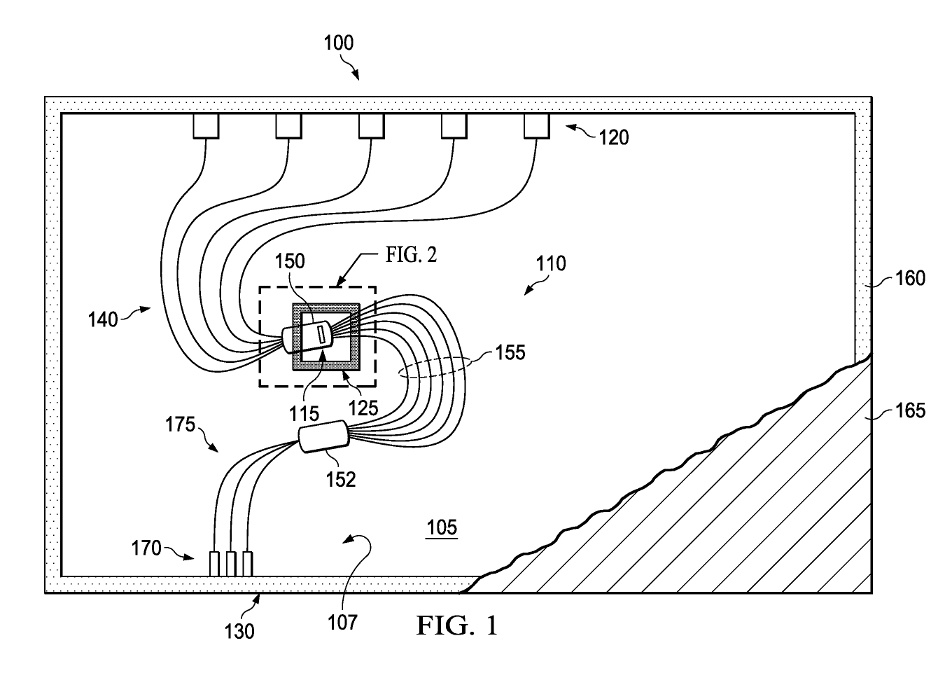

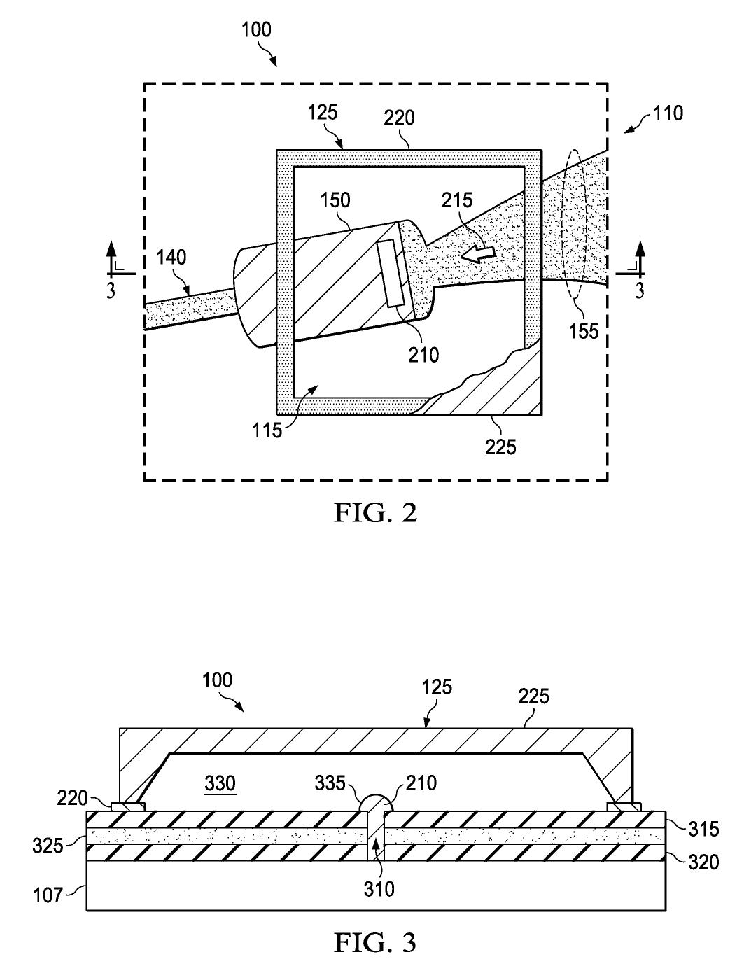

FIG. 1 shows a plan view of a portion of an example optical circuit package 100. FIG. 2 shows a detailed plan view of a portion of the example optical circuit package 100 presented in FIG. 1, corresponding to view 2 in FIG. 1. FIG. 3 shows a cross-sectional view of a portion of the example optical circuit package 100, depicted along in view lines 3-3 in FIG. 2.

With continuing reference to FIGS. 1-3, the optical circuit package 100 comprises a substrate 105 having a planar surface 107 and an interferometric planar lightwave circuit 110 (e.g., an arrayed waveguide grating located on the planar surface 107 of the substrate 105. The package 100 also comprises a refractive-index-compensation material 210 incorporated into a portion 115 of the interferometric planar lightwave circuit 110 such that an optical path 220 through the interferometric planar lightwave circuit 110 passes through the refractive-index-compensation material 210. The package 100 also comprises a moisture or organic vapor sensitive electro-optic device 120 (e.g., avalanche photodiode detectors) located on the substrate 105. The package 100 further comprises an inner hermetic can 125, located on the substrate 105, and, an outer hermetic can 130, located on the substrate 105. The inner hermetic can 125 encapsulates the portion 115 of the planar lightwave circuit 110 incorporating the refractive-index-compensation material 210. The outer hermetic can 130 encloses the planar lightwave circuit 110, the moisture or organic vapor sensitive electro-optic device 120 and the inner hermetic can 125.

The term interferometric planar lightwave circuit, as used herein refers to any optical circuit with two or more optical paths that interfere with each other. Non-limiting examples include an arrayed waveguide grating, Mach-Zender interferometer, a ring resonator or similar devices whose interference effects can be altered by temperature, until compensated for, e.g., by incorporating the refractive-index-compensation material 210 as discussed herein.

The term moisture or organic vapor sensitive electro-optic device, a used here refers to any electro-optic device that could be incorporated on an optical circuit package and whose function can be damaged or function compromised by the presence of moisture or organic vapors. Non-limiting examples include avalanche photodiode detectors, lasers, PIN photodiodes or similar devices familiar to one of ordinary skill.

Although the illustrative example package 100 is discussed below in context of the planar lightwave circuit 110 being or including an arrayed waveguide grating, and, the moisture or organic vapor sensitive electro-optic device 120 being or including avalanche photodiode detectors, the package 100 could include different combinations of different embodiments of circuits 110 and devices 120.

The term refractive-index-compensation material 210, as used herein, refers to a material whose refractive index changes in a direction with increasing temperature that is opposite to the direction of change in the effective refractive index of the waveguide material that the arrayed waveguide grating 110 is composed of. For example, consider an embodiment of the package 100 where the arrayed waveguide grating 110 includes a waveguide material whose effective refractive index increases with increasing temperature (e.g., silica glass). In such an embodiment, the refractive-index-compensation material would be a material whose refractive index decreases with increasing temperature (e.g., a resin material than includes epoxy groups or silicone groups).

One of ordinary skill in the art would understand how to adjust the amount of refractive-index-compensation material 210 incorporated into the arrayed waveguide grating 110, and the optical path 215 so as to compensate for the extent of the temperature-related change in the effective refractive index that the arrayed waveguide grating 110 would otherwise have.

As further illustrated in FIG. 1, in some embodiments of the package 100 at least one of the avalanche photodiode detectors 120 is optically coupled to the arrayed waveguide grating 110, e.g., via waveguides 140 also located on the substrate 105. That is, the arrayed waveguide grating 110 and avalanche photodiode detectors 120 are part of a same optical circuit designed to perform wavelength division multiplexing/demultiplexing. In other embodiments, however, the arrayed waveguide grating 110 and avalanche photodiode detectors 120 can be part of different optical circuits of the package 100, such as an optical transmitter circuit, or, an optical receiver circuit.

As also illustrated for the example package shown in FIG. 1, some embodiments of the arrayed waveguide grating 110 include a first free-space propagation region 150, a second multimode portion 152, and a plurality of single-mode waveguide portion 155. The optical path 215 travels to or from the first multimode portion 150 through the plurality of single-mode waveguide portions 155 and from or to the second multimode portion 152. One of ordinary skill in the art would be familiar with other types of arrayed waveguide grating configurations. In some embodiments, portion 115 of the arrayed waveguide grating 110 that the refractive-index-compensation material 210 is incorporated into includes a free-space propagation region (e.g., one of the first or second free-space propagation regions 150, 152).

As further illustrated in FIGS. 1 and 2, the inner hermetic can 125 encapsulates at least part of the free-space propagation region 150 of the arrayed waveguide grating 110 which incorporates the refractive-index-compensation material 210 therein. In some cases, as further illustrates in FIGS. 1 and 2, the inner hermetic can 125 may also encapsulate other parts of the arrayed waveguide grating 110, such as part of the single-mode waveguide portions 155.

As illustrated in FIG. 3, in some embodiments, the portion 115 of the arrayed waveguide grating 110 that incorporates the refractive-index-compensation material 210 includes a trench 310 in upper and lower cladding layers 315, 320 and in a core layer 325 of a free-space propagation region 150 of the arrayed waveguide grating 110.

In some cases, such as illustrated in FIGS. 2 and 3, the inner hermetic can 125 includes walls 220 and a lid 225 sealed (e.g., via soldering) to the walls 220. So that the underlying features can be seen, only a portion of the lid 225 is depicted. As shown in FIG. 3 in some cases the lid 225 includes a cavity 330. The cavity 330 is configured to enclose a portion 335 of the refractive-index-compensation material 220 located above a surface 340 of the arrayed waveguide grating 110. That is, the lid 225 can be designed to have a cavity 330 that is large enough to cover those portions 335 of the material 210 laying outside of the trench 310 because, e.g., the trench is slightly overfilled with the material 220.

In some embodiments the walls 220 can include a solder and the lid 225 can includes a silicon material. For instance, the walls 220 can be made of a lead-tin solder alloy and the lid 225 can be made of silicon layer micro-machined to fit onto the walls 220, and to include a cavity 330, in some cases. In other embodiments, however, one or both the walls 220 and lid 225 of the inner hermetic can 125 can be made of a metal or metal alloy (e.g., solder), or, a glass material (e.g., silica glass).

Similarly, as shown in FIG. 1 the outer hermetic can 130 can include walls 160 and a cap 165 sealed to the walls 160. Only a portion of the cap 165 is depicted so that underlying features can be seen. Embodiments, of the walls 160 and cap 165 of the outer hermetic can 130 may be composed of metal, glass or other materials that are able to maintain a hermetic seal for those portions of the optical circuit 100 enclosed by the can 130.

Some embodiments of the package 100 can further include one or more fiber couplers 170 located on the substrate 105. At least one of the fiber couplers 170 can be optically coupled to the arrayed waveguide grating 110 and the one or more fiber couplers can be enclosed by the outer hermetic can 125 (except for a facet that is coupled to an optical fiber outside of the package). As illustrated some of the fiber couplers 170 can be optically coupled to the second free-space propagation region 152 of the arrayed waveguide grating 110 via waveguides 175 located on the substrate 105. One of ordinary skill in the art would appreciate how the arrayed waveguide grating can be configured to connect an optical data signal carried in an optical output from the fiber couplers 170 and transferred to arrayed waveguide grating via a set waveguides 175 optically connecting the fiber couplers 170 to the arrayed waveguide grating 110.

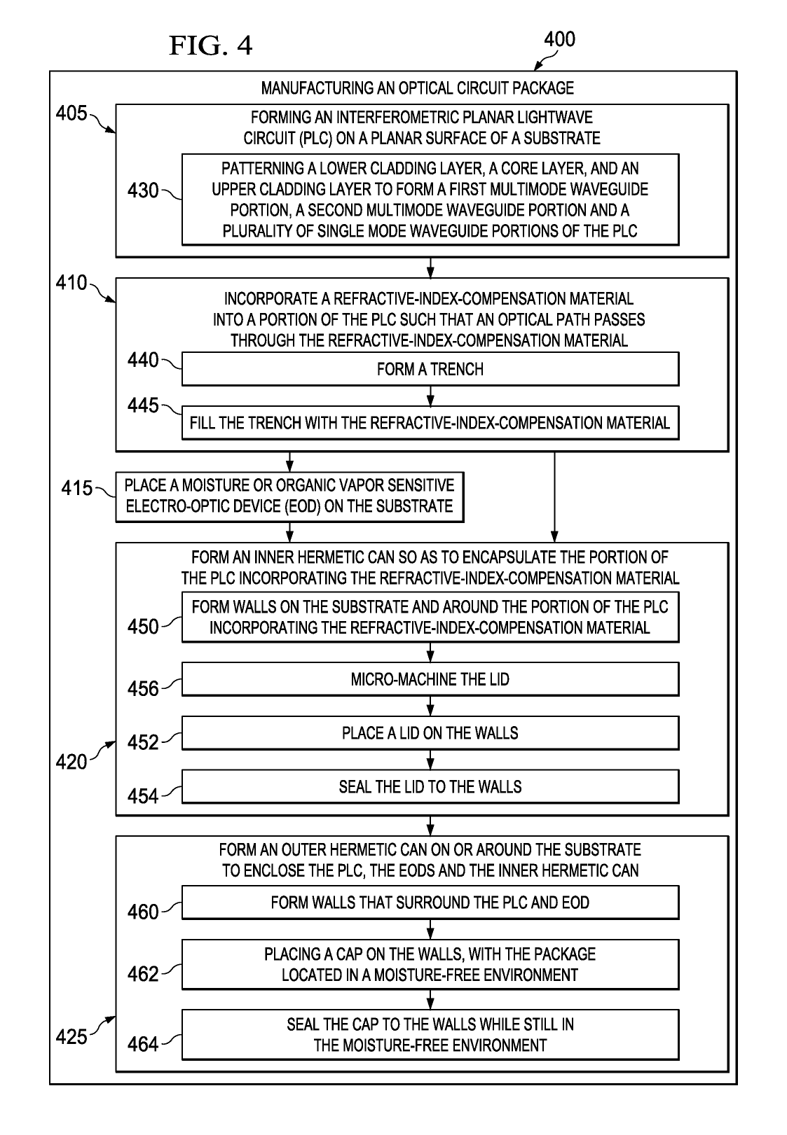

Another embodiment of the disclosure is a method of manufacturing an optical circuit package. FIG. 4 presents a flow diagram of an example method 400 of manufacturing an optical circuit package according to the disclosure, such as the method to manufacture any of the example packages 100 discussed in the context of FIGS. 1-3

With continuing reference to FIGS. 1-3 throughout, the method embodiment depicted in FIG. 4 comprises a step 405 of forming an interferometric planar lightwave circuit 110 (PLC, e.g., an arrayed waveguide grating, Mach-Zender interferometer or a ring resonator) on a planar surface 107 of a substrate 105. The method 400 also comprises a step 410 of incorporating a refractive-index-compensation material 210 into a portion 115 of the interferometric planar lightwave circuit 110 such that an optical path 215 through the interferometric planar lightwave circuit 110 passes through the refractive-index-compensation material 210. The method 400 also comprises a step 415 of placing a moisture or organic vapor sensitive electro-optic device 120 (EOD, e.g., avalanche photodiode detectors, lasers or PIN photodiodes) on the substrate 105. The method 400 also comprises a step 420 of forming an inner hermetic can 125 and a step 425 of forming an outer hermetic can 130. The inner hermetic can 125 is formed, in step 420, so as to encapsulate the portion 115 of the planar lightwave circuit 110 incorporating the refractive-index-compensation material 210. The outer hermetic can is formed, in step 425, on or around the substrate 105 so as to enclose the interferometric planar lightwave circuit 110, the moisture or organic vapor sensitive electro-optic device 120 and the inner hermetic can 125.

In some embodiments, forming an arrayed waveguide grating 110 (or other planar lightwave circuits) on the planar surface 107 of the substrate 105 (step 405) can include a step 430 of patterning a lower cladding layer 320, a core layer 325, and an upper cladding layer 315 to form a first free-space propagation region 150, a second free-space propagation region 152 and a plurality of single mode waveguide portions 155 of the arrayed waveguide grating 110. These waveguide portions 150, 152, 155 can be continuously connected to each other through the material layers 315, 320, 325 that the arrayed waveguide grating 110 is formed from. One skilled in the art would be familiar with techniques such as chemical vapor depositing or flame hydrolysis, or re-melting procedures, to form the cladding layers 315, 320 (e.g., composed of silicon oxides) or the core layer 325 (e.g., composed of silicon). In some cases the patterning step 430 the lower cladding layer, the core layer, and the upper cladding layer can also form waveguides 140 that connect the first free-space propagation region 150 to the avalanche photodiode detector 120, and/or form other waveguides 175 that connect an external optical fiber to the second free-space propagation region 152.

In other embodiments, the arrayed waveguide grating 110 and other light guiding components of the package 100 can be formed in step 405 by depositing and patterned other types of waveguide materials such as indium phosphide (InP), organic polymer core and cladding materials, or other materials familiar to those skilled in the art.

In some cases, the step 415 of placing the plurality of avalanche photodiode detectors 120 (or other moisture or organic vapor sensitive electro-optic devices) on the substrate 105 includes placing pre-formed avalanche photodiode detectors 120 on the substrate 105 with the aid of micro-manipulators, and then soldering the avalanche photodiode detectors 120 in place. In some cases it is desirable to place the avalanche photodiode detectors on the substrate in step 415 after forming the inner hermetic can 125 is step 420 to avoid exposing the avalanche photodiode detectors to any moisture released from the refractive-index-compensation material 210.

In some embodiments of the method 400, incorporating the refractive-index-compensation material 210 into the portion of the arrayed waveguide grating (or other planar lightwave circuit; step 410) includes a step 440 of forming a trench 310 and a step 445 of filling the trench 310 with the refractive-index-compensation material 210. In some cases, forming the trench 310 in step 440 can include masking and the etching (e.g., a dry etch process) the upper and lower cladding layers 150, 152 and core layer 155 in a single or a series of etching processes. In some cases, filling the trench 310 in step 445 can include spin-coating of the refractive-index-compensation material 210 on the substrate 105 or other filling procedures well know to those skilled in the art.

In some embodiments, forming the inner hermetic can 125 (step 420) includes a step 450 of forming walls 220 on the substrate 105 and around the portion 115 of the arrayed waveguide grating 110 (or other planar lightwave circuit) that incorporates the refractive-index-compensation material 210. In some cases, for instance, the walls 220 can be formed in step 450 by depositing a perimeter line of solder around the portion 115 of the arrayed waveguide grating 110 via conventional solder deposition tools. In such cases the walls 220 can be made of solder.

In some embodiments, forming the inner hermetic can 125 (step 420) also includes a step 452 of placing a lid 225 on the walls 220 and a step 454 of sealing the lid 225 to the walls 220. For instance, as part of step 452 the micro-manipulators can be used to place the lid 225 on the walls 220 and, in step 454, the walls 220 and/or lid 225 can be heated so as to form an-air tight seal.

In some cases, step 454, or steps 452 and 454, are performed while the package 110 is in a moisture-free environment, although this is not necessary, because the arrayed waveguide grating portion 115 incorporating the refractive-index-compensation material 210 is atmospherically isolated from the rest of the package 100 including the avalanche photodiode detectors 120 (or other moisture or organic vapor sensitive electro-optic device) by the inner hermetic can 120. That is, in some cases step 454, or steps 452 and 454, can be performed with the optical circuit package 110 located in a moisture-containing environment.

In some embodiments forming the inner hermetic can 125 (step 420) includes a step 456 of includes micro-machining a material layer (e.g., a metal, silicon, silica glass or similar material) to form the lid 225. In some cases as part of step 456 the lid 225 is formed to include a cavity 330, that is configured to enclose a portion 335 of the refractive-index-compensation material 210 located above a surface 340 of the arrayed waveguide grating 110.

In some embodiments of the method 400, forming an outer hermetic can 130 (step 425) includes a step 460 of forming walls 160 that surround the interferometric planar lightwave circuit 110 (e.g. an arrayed waveguide device) or other and moisture or organic vapor sensitive electro-optic device 120 (e.g., avalanche photo detectors) and step 462 of placing a cap 165 on the walls 160, with the optical circuit package 110 located in a moisture-free environment, and a step 464 of sealing the cap 165 to the walls 160 while still in the moisture-free environment. For instance, the walls 160 formed in step 460 can include depositing a line of solder and placing the cap 165 on the walls 160 and then sealing the cap 165 to the walls 160, similar to that discussed in the context of steps 450, 452, and 454, respectively. The moisture-free environment can be formed by placing the package 100 in a chamber with an atmosphere of pure nitrogen, helium, argon or similar gas having a low moisture content, performing steps 462 and 464 with the package 100 in the chamber.

Although the embodiments have been described in detail, those of ordinary skill in the art should understand that they could make various changes, substitutions and alterations herein without departing from the scope of the disclosure.

What is claimed is:

1. An optical circuit package, comprising:
a substrate having a planar surface;
an interferometric planar lightwave circuit located on the planar surface of the substrate;
a refractive-index-compensation material incorporated into a portion of the planar lightwave circuit such that an optical path through the planar lightwave circuit passes through the refractive-index-compensation material;
a moisture or organic vapor sensitive electro-optic device located on the substrate;
an inner hermetic can located on the substrate, wherein the inner hermetic can encapsulates the portion of the planar lightwave circuit incorporating the refractive-index-compensation material; and
an outer hermetic can located on or around the substrate, wherein the outer hermetic can encloses the planar lightwave circuit, the moisture or organic vapor sensitive electro-optic device and the inner hermetic can.

2. The package of claim 1, wherein the planar lightwave circuit includes a Mach-Zender interferometer or a ring resonator.

3. The package of claim 1, wherein the moisture or organic vapor sensitive electro-optic device includes a laser or a PIN photodiode.

4. The package of claim 1, wherein the planar lightwave circuit includes an arrayed waveguide grating and the moisture Or organic vapor sensitive electro-optic device includes avalanche photodiode detectors.

5. The package of claim 4, wherein at least one of the avalanche photodiode detectors is optically coupled to the arrayed waveguide grating.

6. The package of claim 4, wherein the portion of the arrayed waveguide grating that the refractive-index-compensation material is incorporated into includes a free-space propagation region of the arrayed waveguide grating.

7. The package of claim 4, wherein the inner hermetic can encapsulates at least part of a free-space propagation region of the arrayed waveguide grating, the free-space propagation region incorporating the refractive-index-compensation material therein.

8. The package of claim 1, wherein the refractive-index-compensation material is a resin that includes epoxy groups or silicone groups.

9. The package of claim 1, wherein the portion of the planar lightwave circuit that incorporates the refractive-index-compensation material includes a trench in upper and lower cladding layers and in a core layer of a free-space propagation region of an arrayed waveguide grating.

10. The system of claim 1, wherein a lid of the inner hermetic can includes a cavity that is configured to enclose a portion of the refractive-index-compensation material located above a surface of the planar lightwave circuit.

11. The package of claim 1, wherein walls of the inner hermetic can are made of solder and a lid of the inner hermetic can includes a micro-machined silicon structure.

12. The package of claim 1, wherein the package is configured as one of an optical transmitter or receiver component of an optical transceiver system.

13. A method of manufacturing an optical circuit package, comprising:
forming an interferometric planar lightwave circuit located on a planar surface of a substrate;
incorporating a refractive-index-compensation material into a portion of the planar lightwave circuit located such that an optical path through the planar lightwave circuit located passes through the refractive-index-compensation material;
placing a moisture or organic vapor sensitive electro-optic device on the substrate;
forming an inner hermetic can on the substrate so as to encapsulate the portion of the planar lightwave circuit incorporating the refractive-index-compensation material; and
forming an outer hermetic can on or around the substrate so as to enclose the planar lightwave circuit, the moisture or organic vapor sensitive electro-optic device and the inner hermetic can.

14. The method of claim 13, wherein forming the planar lightwave circuit includes forming a Mach-Zender interferometer or a ring resonator.

15. The method of claim 13, wherein placing the moisture or organic vapor sensitive electro-optic device includes placing a laser or a PIN photodiode.

16. The method of claim 13, wherein forming the planar lightwave circuit includes forming an arrayed waveguide grating and placing the moisture or organic vapor sensitive electro-optic device includes placing a plurality avalanche photodiode detectors.

17. The method of claim 16, wherein forming the arrayed waveguide grating on the substrate includes patterning a lower cladding layer, a core layer, and an upper cladding layer to form a first free-space propagation region, a second free-space propagation region and a plurality of single mode waveguide portions of the arrayed waveguide grating.

18. The method of claim 13, wherein incorporating the refractive-index-compensation material into the portion of the planar lightwave circuit located includes:
forming a trench in a lower cladding layer, a core layer, and an upper cladding layer of the planar lightwave circuit; and
filling the trench with the refractive-index-compensation material.

19. The method of claim 13, wherein forming the inner hermetic can on the substrate includes:
forming walls on the substrate and around the portion of the planar lightwave circuit that incorporates the refractive-index-compensation material;
placing a lid on the walls; and
sealing the lid to the walls.

20. The method of claim 13, wherein forming the inner hermetic can on the substrate includes micro-machining a material layer to form a lid for the inner hermetic can, wherein the lid includes a cavity that is configured to enclose a portion of the refractive-index-compensation material located above a surface of the planar lightwave circuit.
